(19) United States
(12) Patent Application Publication
(10) Pub. No.: US 2025/0068090 A1
(43) Pub. Date: Feb. 27, 2025

(54) MECHANICALLY CONTROLLED STRESS-ENGINEERED OPTICAL SYSTEMS AND METHODS

(71) Applicants: ASML NETHERLANDS B.V., Veldhoven (NL); UNIVERSITY OF ROCHESTER, Rochester, NY (US)

(72) Inventors: Adel JOOBEUR, Milford, CT (US); Richard JACOBS, Brookfield, CT (US); Richard Carl ZIMMERMAN, Brookfield, CT (US); Ali BASIRI, Wilton, CT (US); Thomas Gordon BROWN, Rochester, NY (US); Ashan Ariyawansa GALABADA DEWAGE, Norwalk, CT (US)

(73) Assignees: ASML NETHERLANDS B.V., Veldhoven (NL); UNIVERSITY OF ROCHESTER, Rochester, NY (US)

(21) Appl. No.: 18/725,067

(22) PCT Filed: Jan. 2, 2023
(86) PCT No.: PCT/EP2023/050030

§ 371 Date: Jun. 27, 2024

Related U.S. Application Data
(60) Provisional application No. 63/298,006, filed on Jan. 10, 2022.

(51) Int. Cl. G03F 9/00; G03F 7/00

(52) U.S. Cl. CPC G03F 9/7065; G03F 7/70566

(57) ABSTRACT

A fast and dynamic waveplate is described. The present systems and methods utilize stress birefringence that generates inside a plate when force is applied on one or more sides of the plate. The force is applied using one or more actuators distributed along the side(s) of the plate. The magnitude of the force can be controlled using a control unit. A generated stress birefringence is spatially varying across the plate. By carefully adjusting the force, the plate can be converted into a waveplate with an arbitrary value of retardance that is determined by the force. Since the parameter that determines the birefringence is force, a control unit can be used to apply different combinations of force values at a sub-millisecond speed to achieve fast control of the value of the birefringence as well as an orientation in the plate.

### CROSS-REFERENCE TO RELATED APPLICATIONS

This application claims priority of U.S. Provisional Patent Application No. 63/298,006, which was filed on Jan. 10, 2022, and which is incorporated herein in its entirety by reference.

### TECHNICAL FIELD

This description relates generally to mechanically controlled stress-engineered optical systems and methods.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate includes a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices as described herein can be gleaned, for example, from U.S. Pat. No. 6,046,792, incorporated herein by reference.

Prior to transferring the pattern from the patterning device to the substrate, the substrate may undergo various procedures, such as priming, resist coating, and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, deposition, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, deposition, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, deposition, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but are not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

### SUMMARY

The present systems and methods utilize the stress birefringence that is generated inside a (e.g., glass or crystal) plate when force is applied on the side(s) of the plate. The force is applied using a set of piezoelectric actuators that are distributed symmetrically along the side(s) of the plate. The actuators are controlled electronically. By carefully adjusting the applied force, the plate can be converted into a waveplate with an arbitrary value of retardance that is determined by the force. Since the force determines the birefringence, different combinations of force values can be applied electronically at a sub-millisecond speed to achieve fast control of the value of the birefringence as well as an orientation of a fast and/or slow axis in the plate (the plate itself stays stationary), creating a fast and dynamic waveplate.

According to an embodiment, a system configured to condition light for metrology is provided. The system comprises an optically transparent plate, one or more actuators configured to apply forces to the plate to generate a stress pattern in the plate, and one or more processors configured to control the one or more actuators to apply the forces to generate the stress pattern to impart a specific polarization to light passing through the plate in accordance with a desired metrology function.

In some embodiments, responsive to the forces being applied to the plate, the plate comprises a waveplate.

In some embodiments, the plate comprises a transparent material, and, responsive to the forces being applied to the plate to generate the stress pattern, the plate is configured to change the light passing through the plate from a first polarization state to a second polarization state.

In some embodiments, the applied forces induce an orientation and a retardance in the plate. The induced retardance and orientation are not uniform. Each varies across the plate. A center region of the plate is an area of interest where the retardance and fast axis orientation are approximately uniform.

In some embodiments, the orientation is controlled by locations and/or a distribution of forces applied to the plate by the one or more actuators.

In some embodiments, the retardance is controlled by magnitudes of forces applied to the plate by the one or more actuators.

In some embodiments, the plate comprises glass or crystal.

In some embodiments, the one or more actuators are piezoelectric.

In some embodiments, the stress pattern comprises birefringence.

In some embodiments, the one or more processors are configured to individually control each of the one or more actuators such that the stress pattern inside the plate is dynamically adjustable before, during, and/or after the light passes through the plate.

In some embodiments, dynamic adjustments comprise applications of different combinations of force magnitudes at different actuators around the plate to change birefringence in the plate with sub-millisecond control speeds.

In some embodiments, dynamic adjustments comprise applications of different combinations of force magnitudes at different actuators around the plate to change an orientation in the plate with sub-millisecond control speeds.

In some embodiments, the one or more actuators are arranged on one or more edges of the plate.

In some embodiments, the one or more actuators comprise a plurality of actuators distributed symmetrically around one or more edges of the plate.

In some embodiments, the plate, the one or more actuators, and the one or more processors are configured such that the light passing through the plate can have a wavelength that ranges from about 300 nanometers to about 1.5 micrometers.

In some embodiments, imparting a specific polarization to the light comprises conditioning the light passing through the plate for metrology.

In some embodiments, the system further comprises a polarizer and a sensor, wherein the sensor is configured to generate a metrology signal based on light received by the sensor after the light passes through the polarizer and the plate.

In some embodiments, the sensor is included in a camera.

In some embodiments, the system further comprises an imaging lens positioned between the plate and the sensor.

In some embodiments, the metrology signal comprises an overlay signal associated with a semiconductor manufacturing process.

According to another embodiment, a method for conditioning light for metrology is provided. The method comprises applying forces to an optically transparent plate with one or more actuators to generate a stress pattern in the plate; and controlling, with one or more processors, the one or more actuators to apply the forces to generate the stress pattern to impart a specific polarization to light passing through the plate in accordance with a desired metrology function.

According to another embodiment, there is provided a non-transitory computer readable medium having instructions thereon, the instructions when executed by a computer, causing operations comprising: applying forces to an optically transparent plate with one or more actuators to generate a stress pattern in the plate; and controlling, with one or more processors, the one or more actuators to apply the forces to generate the stress pattern to impart a specific polarization to light passing through the plate in accordance with a desired metrology function.

According to another embodiment, a system configured to condition light for an overlay measurement as part of a semiconductor manufacturing process is provided. The system is configured to dynamically adjust birefringence and/or an orientation in an optical plate before, during, and/or after light passes through the plate. The dynamic adjustments comprise applications of different combinations of force magnitudes at different actuators around the plate to change the birefringence and/or the orientation in the plate with sub-millisecond control speeds. The system comprises the plate. The plate comprises a transparent material and is configured to change the light passing through the plate from a first polarization state to a second polarization state responsive to forces being applied to the plate by the different actuators. The system comprises the different actuators. The different actuators comprise a plurality of piezoelectric actuators distributed symmetrically around one or more edges of the plate. The plurality of piezoelectric actuators are configured to apply forces to the plate to generate the birefringence and/or the orientation. The system comprises one or more processors configured to individually control each one of the plurality of actuators to apply the forces to generate the birefringence and/or the orientation such that a specific polarization is imparted to the light passing through the plate that changes the light to the second polarization state.

### BRIEF DESCRIPTION OF THE DRAWINGS

The above aspects and other aspects and features will become apparent to those ordinarily skilled in the art upon review of the following description of specific embodiments in conjunction with the accompanying figures.

FIG. 1 schematically depicts a lithography apparatus, according to an embodiment.

FIG. 2 schematically depicts an embodiment of a lithographic cell or cluster, according to an embodiment.

FIG. 3 schematically depicts an example inspection system, according to an embodiment.

FIG. 4 schematically depicts additional details of the example inspection system, according to an embodiment.

FIG. 5 illustrates the relationship between a radiation illumination spot of an inspection system and a metrology target, according to an embodiment.

FIG. 6 illustrates a process of deriving a plurality of variables of interest based on measurement data, according to an embodiment.

FIG. 7 illustrates a system configured to condition light for metrology, which may form a portion of the system shown in FIG. 3 and FIG. 4, according to an embodiment.

FIG. 8 illustrates another embodiment of the system shown in FIG. 7, according to an embodiment.

FIG. 9 illustrates a mapped stress distribution and an orientation in a (stress engineered optical) plate that results from forces applied by actuators coupled to the plate, according to an embodiment.

FIG. 10 illustrates an image of another (stress engineered optical) plate between two cross polarizers while forces are applied to the plate by actuators, according to an embodiment.

FIG. 11 illustrates a polarization state of light after it has passed through a center portion (e.g., an aperture) of a stress engineered optical plate, according to an embodiment.

FIG. 12 illustrates a method for conditioning light for metrology, according to an embodiment.

FIG. 13 is a block diagram of an example computer system, according to an embodiment.

FIG. 14 is a schematic diagram of a lithographic projection apparatus similar to FIG. 1, according to an embodiment.

FIG. 15 is a more detailed view of the apparatus in FIG. 14, according to an embodiment.

FIG. 16 is a more detailed view of the source collector module of the apparatus of FIG. 14 and FIG. 15, according to an embodiment.

### DETAILED DESCRIPTION

Stressed engineered optics (SEO's) exist as fixed waveplates that have fixed force points on the side(s) of the (usually glass) plate. No active control methods have been implemented on such plates. Existing polarization control systems typically include liquid crystal and can be quickly adjusted due to their electronic controllability. However, the response time in these systems can be larger than a few milliseconds due to the slow orienting of the crystals. Also, the polarization state in such systems often drifts over time. Conventional rotating polarizer/waveplate systems are slow to achieve control of polarization angles, for example.

Advantageously, the present systems and methods utilize the stress birefringence that is generated inside a (glass or crystal) plate when force is applied on the side(s) of the plate. The force is applied using a set of actuators that are distributed symmetrically along the side(s) of the plate. The magnitude of the force can be controlled electronically. A generated stress birefringence is spatially varying across the plate. By carefully adjusting the force, the plate can be converted into a waveplate with an arbitrary value of retardance that is determined by the force. Since the force determines the birefringence, different combinations of force values can be applied electronically at a sub-millisecond speed to achieve fast control of the value of the birefringence as well as an orientation of a fast and/or slow axis in the plate (with the plate itself staying stationary), creating a fast and dynamic waveplate.

By way of a brief introduction, the description herein relates generally to semiconductor device manufacturing and patterning processes. More particularly, the following paragraphs describe several components of a semiconductor manufacturing system and/or related systems. As described herein these systems and methods may be used for measuring overlay in a semiconductor device manufacturing process, for example, or for other operations.

Although specific reference may be made in this text to the measurement of overlay and the manufacture of integrated circuits (ICs) for semiconductor devices, it should be understood that the description herein has many other possible applications. For example, it may be employed in the measurement of alignment and/or other parameters. It may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

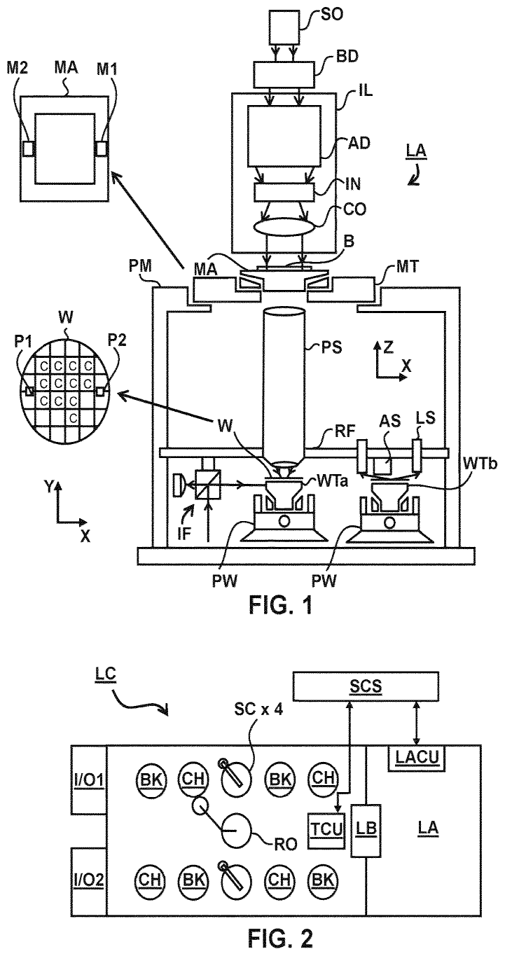

FIG. 1 schematically depicts an embodiment of a lithographic apparatus LA. The apparatus comprises an illumination system (illuminator) IL configured to condition a radiation beam B (e.g. UV radiation, DUV radiation, or EUV radiation); a support structure (e.g. a mask table) MT constructed to support a patterning device (e.g. a mask) MA and connected to a first positioner PM configured to accurately position the patterning device in accordance with certain parameters; a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame RF. As depicted, the apparatus is of a transmissive type (e.g. employing a transmissive mask). Alternatively, the apparatus may be of a reflective type (e.g. employing a programmable mirror array, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as σ-outer and σ-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic or other types of optical components, or any combination thereof, for directing, shaping, or controlling radiation.

Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in a target portion of the device, such as an integrated circuit.

A patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z, or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g. astigmatic) and/or a high frequency shape (e.g. free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be carried out on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate. An immersion liquid may also be applied to other spaces in the lithographic apparatus, for example, between the patterning device and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder, 2-D encoder or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes. In step mode, the support structure MT and the substrate table WT are kept essentially stationary, while a pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above-described modes of use or entirely different modes of use may also be employed.

The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already includes multiple processed layers.

The terms “radiation” and “beam” used herein with respect to lithography encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, CD, edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns.

As shown in FIG. 2, the lithographic apparatus LA may form part of a lithographic cell LC, also sometimes referred to a lithocell or cluster, which also includes apparatuses to perform pre-and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)).

The one or more measured parameters may include, for example, alignment, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement is often performed on a dedicated metrology target provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. As discussed above, a fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. Traditionally, this may be termed diffraction-based metrology. One such application of this diffraction-based metrology is in the measurement of overlay. For example, alignment can be measured by comparing parts of the diffraction spectrum (for example, comparing different diffraction orders in the diffraction spectrum of a periodic grating).

Thus, in a device fabrication process (e.g., a patterning process or a lithography process), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)). The SMASH (SMart Alignment Sensor Hybrid) system, as described in U.S. Pat. No. 6,961,116, which is incorporated by reference herein in its entirety, employs a self-referencing interferometer that produces two overlapping and relatively rotated images of an alignment marker, detects intensities in a pupil plane where Fourier transforms of the images are caused to interfere, and extracts the positional information from the phase difference between diffraction orders of the two images which manifests as intensity variations in the interfered orders.

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those portions which meet specifications. Other manufacturing process adjustments are contemplated.

A metrology system may be used to determine one or more properties of the substrate structure, and in particular, how one or more properties of different substrate structures vary, or different layers of the same substrate structure vary from layer to layer. The metrology system may be integrated into the lithographic apparatus LA or the lithocell LC, or may be a stand-alone device.

To enable the metrology, often one or more targets are specifically provided on the substrate. A target may include an alignment mark, for example, and/or other targets. Typically, the target is specially designed and may comprise a periodic structure. For example, the target on a substrate may comprise one or more 1-D periodic structures (e.g., geometric features such as gratings), which are printed such that after development, the periodic structural features are formed of solid resist lines. As another example, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

In some embodiments, one of the parameters of interest of a patterning process is overlay. Overlay can be measured using dark field scatterometry in which the zeroth order of diffraction (corresponding to a specular reflection) is blocked, and only higher orders processed. Examples of dark field metrology can be found in PCT patent application publication nos. WO 2009/078708 and WO 2009/106279, which are hereby incorporated in their entirety by reference. Further developments of the technique have been described in U.S. patent application publications US2011-0027704, US2011-0043791 and US2012-0242970, which are hereby incorporated in their entirety by reference. Diffraction-based overlay using dark-field detection of the diffraction orders enables overlay measurements on smaller targets. These targets can be smaller than the illumination spot and may be surrounded by device product structures on a substrate. In an embodiment, multiple targets can be measured in one radiation capture.

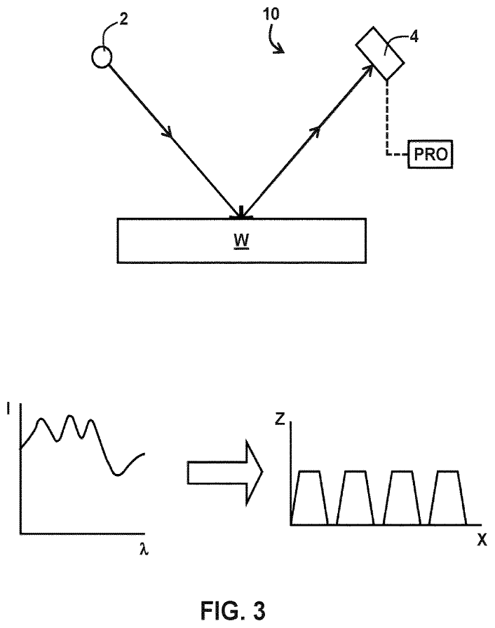

FIG. 3 depicts an example inspection system 10 that may be used to determine overlay and/or perform other metrology operations. It comprises a radiation source 2 which projects or otherwise irradiates radiation onto a substrate W (e.g., which may typically include an overlay target). The redirected radiation is passed to a sensor such as a spectrometer detector 4 and/or other sensors, which measures a spectrum (intensity as a function of wavelength) of the specular reflected and/or diffracted radiation, as shown, e.g., in the graph on the left of FIG. 3. The sensor may generate an overlay signal conveying overlay data indicative of properties of the reflected radiation, for example. From this data, the structure or profile giving rise to the detected spectrum may be reconstructed by one or more processors PRO, a generalized example of which is shown in FIG. 3, or by other operations.

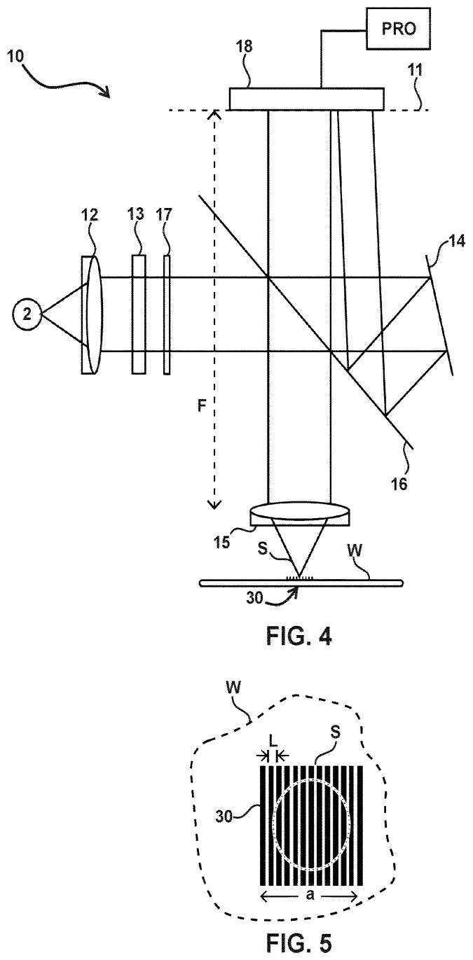

FIG. 4 illustrates additional possible details of inspection system 10 shown in FIG. 3. As shown in FIG. 4, the radiation emitted by radiation source 2 is collimated using lens system 12 and transmitted through interference filter 13 and polarizer 17, reflected by partially reflecting surface 16 and is focused into a spot S on substrate W via an objective lens 15, which has a high numerical aperture (NA) (e.g., at least 0.9 or at least 0.95). An immersion inspection apparatus (using a relatively high refractive index fluid such as water) may have a numerical aperture over 1.

As in lithographic apparatus LA in FIG. 1, one or more substrate tables (not shown in FIG. 4) may be provided to hold the substrate W during measurement operations. The one or more substrate tables may be similar or identical in form to the substrate table WT (a or b) of FIG. 1. In an example where inspection system 10 is integrated with the lithographic apparatus, they may be the same substrate table. Coarse and fine positioners may be provided and configured to accurately position the substrate in relation to a measurement optical system. Various sensors and actuators are provided, for example, to acquire the position of a target portion of interest of a structure (e.g., an overlay target), and to bring it into position under an objective lens. Typically, many measurements will be made on target portions of a structure at different locations across the substrate W. The substrate support can be moved in X and Y directions to acquire different targets, and in the Z direction to obtain a desired location of the target portion relative to the focus of the optical system. It is convenient to think and describe operations as if the objective lens is being brought to different locations relative to the substrate, when, for example, in practice the optical system may remain substantially stationary (typically in the X and Y directions, but perhaps also in the Z direction) and the substrate moves. Provided the relative position of the substrate and the optical system is correct, it does not matter in principle which one of those is moving, or if both are moving, or a combination of a part of the optical system is moving (e.g., in the Z and/or tilt direction) with the remainder of the optical system being stationary and the substrate is moving (e.g., in the X and Y directions, but also optionally in the Z and/or tilt direction).

The radiation redirected by the substrate W then passes through partially reflecting surface 16 into a detector 18 in order to have the spectrum detected. The detector 18 may be located at a back-projected focal plane 11 (i.e., at the focal length of lens 15) or the plane 11 may be re-imaged with auxiliary optics (not shown) onto the detector 18. The detector may be a two-dimensional detector so that a two-dimensional angular scatter spectrum of a substrate target 30 can be measured. The detector 18 may be, for example, an array of CCD or CMOS sensors, and may use an integration time of, for example, 40 milliseconds per frame. Detector 18 shown in FIG. 4 may be similar to and/or the same as detector 4 shown in FIG. 3, for example.

A reference beam may be used, for example, to measure the intensity of the incident radiation. To do this, when the radiation beam is incident on the partially reflecting surface 16 part of it is transmitted through the partially reflecting surface 16 as a reference beam towards a reference mirror 14. The reference beam is then projected onto a different part of the same detector 18 or alternatively on to a different detector (not shown).

One or more interference filters 13 are available to select a wavelength of interest. The interference filter may be tunable rather than comprising a set of different filters. A grating may be used instead of an interference filter. An aperture stop or spatial light modulator (not shown) may be provided in the illumination path to control the range of angle of incidence of radiation on the target.

Detector 18 may measure the intensity of redirected radiation at a single wavelength (or narrow wavelength range), the intensity separately at multiple wavelengths or integrated over a wavelength range, and/or may measure in other ways. Detector 18 may separately measure the intensity of transverse magnetic- and transverse electric-polarized radiation and/or the phase difference between the transverse magnetic- and transverse electric-polarized radiation.

Target 30 on substrate W may be a 1-D grating, which is printed such that after development, the bars are formed of solid resist lines. Target 30 may be a 2-D grating, which is printed such that after development, the grating is formed of solid resist pillars or vias in the resist. The bars, pillars or vias may be etched into or on the substrate (e.g., into one or more layers on the substrate). The pattern (e.g., of bars, pillars or vias) is sensitive to changes in processing in the patterning process (e.g., optical aberration in the lithographic projection apparatus (particularly the projection system PS), focus change, dose change, etc.) and may manifest in a variation in the printed grating. Accordingly, the measured data of the printed grating may be used to reconstruct the grating. One or more parameters of the 1-D grating, such as line width and/or shape, or one or more parameters of the 2-D grating, such as pillar or via width or length or shape, may be input to the reconstruction process, performed by processor PRO, from knowledge of the printing step and/or other inspection processes.

In addition to measurement of a parameter by reconstruction, angle resolved scatterometry is useful in the measurement of asymmetry of features in product and/or resist patterns. A particular application of asymmetry measurement is for the measurement of overlay, where target 30 comprises one set of periodic features superimposed on another. The concepts of asymmetry measurement using the instrument of FIG. 3 or FIG. 4 are described, for example, in U.S. patent application publication US2006-066855, which is incorporated herein in its entirety. While the positions of the diffraction orders in the diffraction spectrum of the target are determined by the periodicity of the target, asymmetry in the diffraction spectrum is indicative of asymmetry in the individual features which make up the target. In the system of FIG. 4, where detector 18 may be an image sensor, such asymmetry in the diffraction orders appears directly as asymmetry in the pupil image recorded by detector 18. This asymmetry can be measured by digital image processing with a processor PRO, and calibrated against known values of overlay, for example.

FIG. 5 illustrates a plan view of a typical target 30, and the extent of illumination spot S in the apparatus of FIG. 4. To obtain a diffraction spectrum that is free of interference from surrounding structures, target 30, in some embodiments, may be a periodic structure (e.g., grating) larger than the width (e.g., diameter) of the illumination spot S. The width of spot S may be smaller than the width and length of the target. The target may be ‘underfilled’ by the illumination, and the diffraction signal may be essentially free from signals from product features and the like outside the target itself. The illumination arrangement 2, 12, 13, 17 (FIG. 4) may be configured to provide illumination of a uniform intensity across a back focal plane of lens 15. Alternatively, by, for example, including an aperture in the illumination path, illumination may be restricted to on axis or off axis directions.

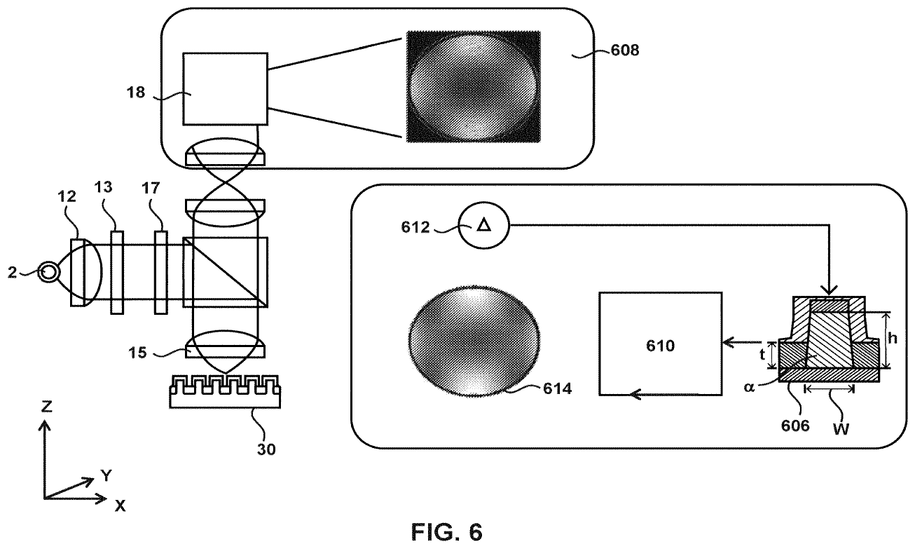

FIG. 6 schematically depicts an example process for determining a value of one or more variables of interest of target 30 based on measurement data obtained using metrology. Radiation detected by detector 18 provides a measured radiation distribution 608 for target 30. For a given target 30, a radiation distribution 612 can be computed/simulated from a parameterized model 606 using, for example, a numerical Maxwell solver 610. The parameterized model 606 shows example layers of various materials making up, and associated with, target 30. The parameterized model 606 may include one or more of variables for the features and layers of the portion of the target under consideration, which may be varied and derived. As shown in FIG. 6, the one or more of the variables may include the thickness t of one or more layers, a width w (e.g., CD) of one or more features, a height h of one or more features, and/or a sidewall angle a of one or more features. Although not shown, the one or more of the variables may further include, but is not limited to, the refractive index (e.g., a real or complex refractive index, refractive index tensor, etc.) of one or more of the layers, the extinction coefficient of one or more layers, the absorption of one or more layers, resist loss during development, a footing of one or more features, and/or line edge roughness of one or more features. The initial values of the variables may be those expected for the target being measured. The measured radiation distribution 608 is then compared at 612 to the computed radiation distribution 612 to determine the difference between the two. If there is a difference, the values of one or more of the variables of the parameterized model 606 may be varied, a new computed radiation distribution 612 calculated and compared against the measured radiation distribution 608 until there is sufficient match between the measured radiation distribution 608 and the computed radiation distribution 612. At that point, the values of the variables of the parameterized model 606 provide a good or best match of the geometry of the actual target 30. In an embodiment, there is sufficient match when a difference between the measured radiation distribution 608 and the computed radiation distribution 612 is within a tolerance threshold.

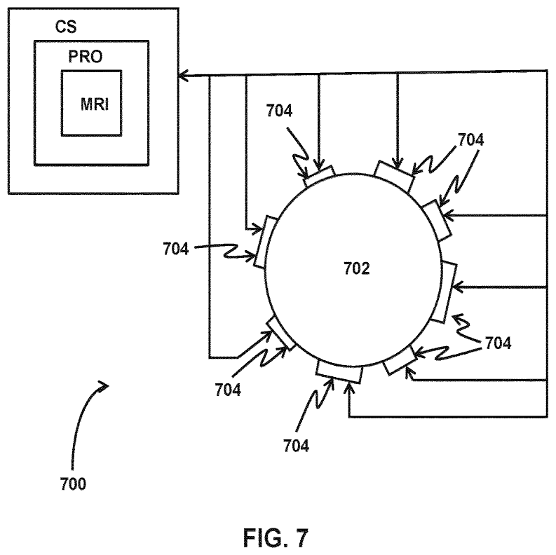

FIG. 7 illustrates a system 700 configured to condition radiation such as light for metrology. System 700 may form a portion of system 10 described above with respect to FIG. 3 and FIG. 4, for example. System 700 may be a subsystem of system 10, for example. In some embodiments, one or more components of system 700 may be similar to and/or the same as one or more components of system 10. In some embodiments, one or more components of system 700 may replace, be used with, and/or otherwise augment one or more components of system 10.

System 700 comprises an optically transparent plate 702, one or more actuators 704, one or more processors PRO, and/or other components. Together, plate 702, actuators 704, processors PRO, and/or other components, form a mechanically controlled stress-engineered optical waveplate for fast and active polarization control, as described herein. System 700 utilizes the stress birefringence that generates inside (e.g., glass or crystal, and/or other transparent) plate 702 when force is applied on the side(s) of plate 702. The force is applied using actuators 704 that are distributed along the side(s) of plate 702. The magnitude of the force can be controlled using processors PRO. The described (e.g., fast and dynamic) polarization control enables better accuracy and/or robustness for overlay measurements (as one example) by minimizing sensitivity to nuisance asymmetries (e.g., changes in side wall angle, floor tilt, etc.) in a patterned substrate, and maximizing sensitivity to features associated with overlay metrology. In some embodiments, system 700 may be configured to replace a conventional rotating waveplate and/or other devices, and may increase the speed of the system (e.g., system 10 shown in FIG. 4) for which the polarization orientation changes to less than millisecond.

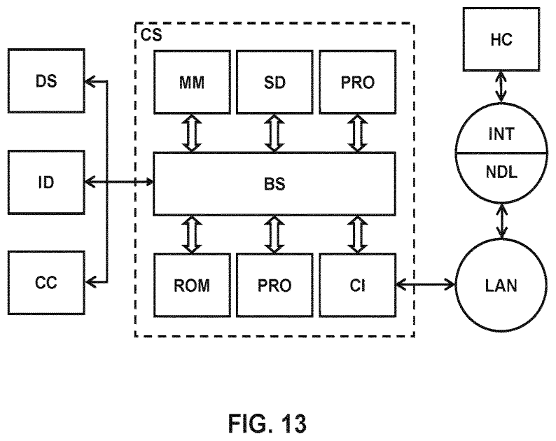

Processors PRO may be included in a computing system CS and may operate based on computer or machine readable instructions MRI (e.g., as described below related to FIG. 13). One or more components of system 700 may bidirectionally communicate with each other as shown in FIG. 7, and/or with one or more components of system 10 shown in FIGS. 3 and 4. Communication may occur by transmitting electronic signals between separate components, transmitting data between separate components, transmitting values between separate components, and/or other communication. The components of system 700 may communicate via wires or wirelessly via a network, such as the Internet or the Internet in combination with various other networks, like local area networks, cellular networks, or personal area networks, internal organizational networks, and/or other networks.

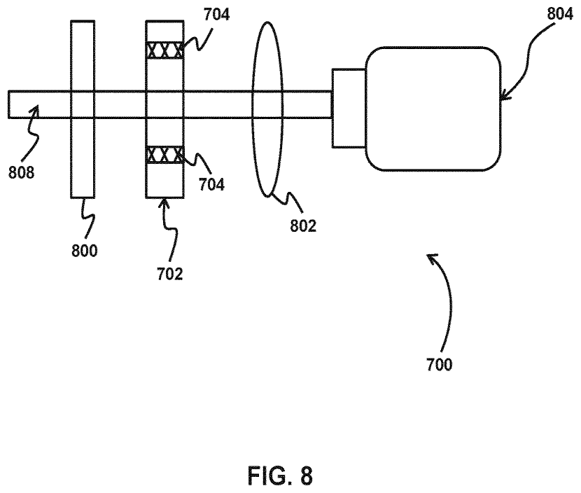

In some embodiments, as shown in FIG. 8, system 700 also includes a polarizer 800, an imaging lens 802, a sensor 804, and/or other components. Sensor 804 is configured to generate a metrology signal based on light 808 received by sensor 804 after light 808 passes through polarizer 800 and plate 702. In some embodiments, sensor 804 is included in a camera and/or other devices. In some embodiments, sensor 804 is the same as or similar to detector 4 shown in FIG. 3 and/or detector 18 shown in FIG. 4. As shown in FIG. 8, imaging lens 802 may be positioned between plate 702 and sensor 804. In some embodiments, imaging lens 802 is the same as or similar to (but may be an additional instance of) one of the lenses or lens systems shown in FIG. 4 and described above. In some embodiments, polarizer 800 is the same as or similar to (but may be an additional instance of) polarizer 17 shown in FIG. 4.

Returning to FIG. 7, plate 702 comprises an optically transparent material. Plate 702 may be formed from any transparent material that has a stress optic coefficient. A stress optic coefficient is defined by a ratio of stress in plate 702 to birefringence. Birefringence is an optical property of a material. The material has a refractive index that depends on the polarization and propagation direction of light. Birefringence can be stress-induced (e.g., by actuators 704), as described herein. In some embodiments, plate 702 comprises glass, crystal, and/or other optically transparent materials that exhibit these characteristics.

Plate 702 may have a round cross-sectional shape (e.g., as shown in FIG. 7), square, rectangular, and/or other cross-section shapes. Plate 702 may have a certain thickness and/or other characteristics. The shape and/or dimensions of plate 702 may be determined by a user, for example, based on the material used for plate 702, the application (e.g., measuring overlay) plate 702 is used for, optical behavior requirements of plate 702, handling requirements of plate 702, and/or based on other factors.

A stress pattern may be generated in plate 702 when one or more forces are applied to plate 702. The stress pattern comprises and/or is otherwise associated with birefringence (e.g., as described above). Responsive to application of the one or more stresses, plate 702 is configured to change light passing through plate 702 from a first polarization state to a second polarization state. In some embodiments, plate 702, along with one or more actuators 704, and the one or more processors PRO are configured such that the light passing through plate 702 can have a wavelength that ranges from about 300 nanometers to about 1.5 micrometers, and plate 702 is configured to change such light from the first polarization state to the second polarization state. For example, a first polarization state may be vertical. A second polarization state may be horizontal. The transmitted wavelength range of light passing through plate 702 is large compared to prior systems because the range depends on the material used for plate 702, and the large aperture that is able to be produced by the birefringence and then dynamically controlled in plate 702. The aperture can be more than 10 mm, for example. A larger wavelength range leads to more flexible instrument design and the ability to carry out measurements at many wavelengths, increasing the ultimate accuracy.

One or more actuators 704 are configured to apply forces to plate 702 to generate the stress pattern and/or cause birefringence in plate 702. Actuators 704 are arranged on one or more edges of plate 702. Actuators may be coupled to one or more edges of plate 702 by adhesive, clips, clamps, screws, a collar, and/or other mechanisms. In some embodiments, the actuators are coupled to plate 702, but not actually attached to plate 702. Instead, actuators 704 are held in contact with plate 702 by constraining forces (a ‘pre-load’) that keeps them in contact with an edge of plate 702. In some embodiments, actuators 704 comprise a plurality of actuators distributed symmetrically around one or more edges of plate 702. Eight different actuators 704 are distributed symmetrically around an edge (e.g., plate 702 only has one edge in FIG. 7) of plate 702 in FIG. 7. This is not intended to be limiting. Other quantities and arrangements of actuators 704 are contemplated.

Actuators 704 are configured to be controlled electronically. Individual actuators 704 are configured to convert an electrical signal into mechanical displacement or stress. The mechanical displacement is configured to apply force to plate 702, which induces stress in plate 702. Actuators 704 each comprise a high precision force application mechanism. Individual actuators 704 can control a small mechanical displacement at high speed (e.g., sub milli-second).

In some embodiments, one or more of actuators 704 are piezoelectric. A piezoelectric actuator operates based on the piezoelectric effect. The piezoelectric effect is the ability of some materials to generate mechanical stress in response to an electric charge. A piezoelectric actuator 704 is configured to convert an electrical signal (or electrical energy generally) into the mechanical displacement. The electrical signal may be sent by processor(s) PRO or computer system CS, for example. An example of an actuator 704 may be a Thorlabs models PA4HKW or others of the PA series.

Responsive to the forces being applied to plate 702, plate 702 comprises a waveplate, for example. A waveplate is configured to change the polarization state of light passing through the waveplate. For example, the polarization state may change from a first state to a second state as described above. The forces applied by actuators 704 induce an orientation and a retardance in plate 702. The orientation is controlled by locations and/or a distribution of forces applied to plate 702 by actuators 704. The retardance is controlled by magnitudes of forces applied to plate 702 by actuators 704. Retardance comprises a difference in optical phase shifts between two polarization directions for light passing through plate 702, for example. The induced retardance and orientation are not uniform. Each varies across the plate. A center region of the plate is an area of interest where the retardance and fast axis orientation is approximately uniform.

One or more processors PRO are configured to control actuators 704. Processors PRO are configured to control actuators 704 to apply the forces to generate the stress pattern to impart a specific polarization to light passing through plate 702. This may be done in accordance with a desired metrology function. The desired metrology function may be measurement of overlay and/or other parameters, for example. The forces are configured to generate the stress pattern to impart a specific polarization to light passing through the plate in accordance with the desired metrology function. Imparting a specific polarization to the light comprises conditioning the light passing through the plate for metrology.

One or more processors PRO are configured to individually control each of the one or more actuators 704 such that the stress pattern inside plate 702 is dynamically adjustable before, during, and/or after the light passes through plate 702. In some embodiments, dynamic adjustments comprise applications of different combinations of force magnitudes at different actuators 704 around plate 702 to change birefringence in plate 702 with sub-millisecond control speeds. In some embodiments, dynamic adjustments comprise applications of different combinations of force magnitudes at different actuators 704 around plate 702 to change an orientation in plate 702 with sub-millisecond control speeds.

The generated stress birefringence is spatially varying across plate 702. By precisely controlling and adjusting the forces applied by actuators 704, a central region and/or other regions of plate 702 can be converted into a waveplate with an arbitrary value of retardance that is determined by the force(s). Since the parameter that determines the birefringence is force, processor(s) PRO can be used to apply different combinations of force values at a sub-millisecond speed to achieve fast control of the value of the birefringence as well as the orientation. System 700 provides arbitrary control of retardance and the orientation with sub-millisecond speed. Thus, plate 702 acts as a fast and dynamic waveplate.

The orientation may be a fast axis orientation, for example. The stress distribution described above causes the glass material of plate 702 to act as a birefringent material where it results in different refractive indices for different polarization states. The slow/fast axis is the direction of the oscillation of the polarization state which sees the higher/lower refractive index.

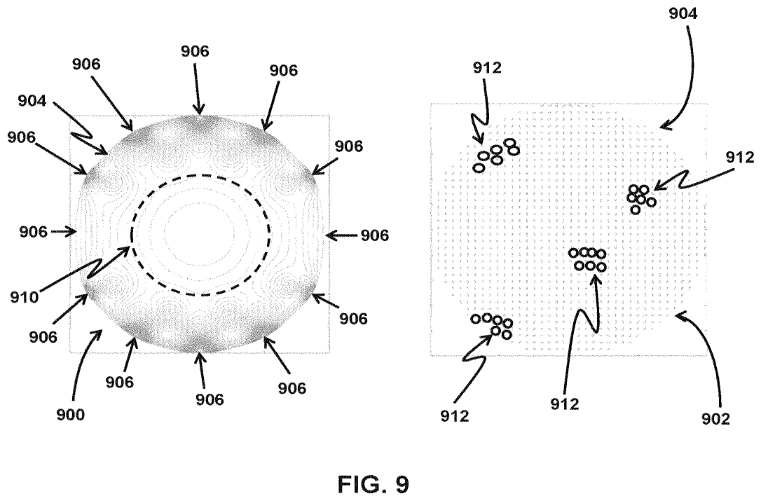

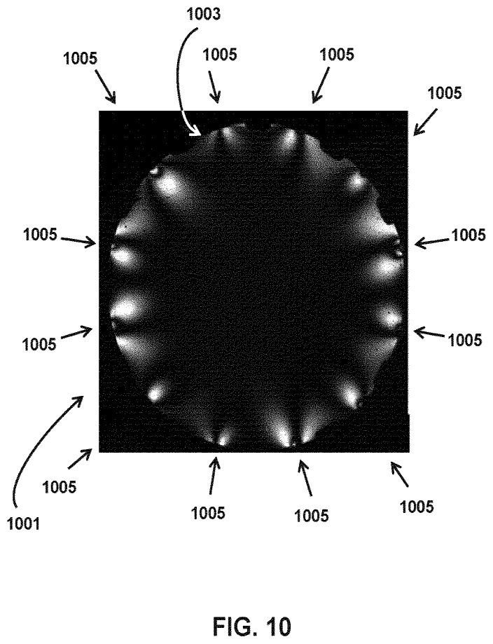

FIG. 9-11 illustrate different aspects of system 700 described above.

FIG. 9 illustrates a mapped stress pattern 900 and an orientation 902 in a plate 904 that results from forces applied by actuators (e.g. such as actuators 704) coupled to plate 904. Plate 904 may be similar to and/or the same as plate 702 described above. In this example, the actuators are not visible. However, the approximate locations 906 of the actuators are apparent from stress pattern 900. Stress pattern 900 shows contours 908 of equal differential stress. Stress pattern 900 comprises and/or is associated with birefringence (e.g., as described above), which is caused by the force applied by the actuators. The generated stress birefringence is spatially varying across plate 904. Responsive to application of the one or more stresses by the actuators, plate 904 is configured to change light passing through plate 904 from a first polarization state to a second polarization state. In some embodiments, light passing through plate 904 can have a wavelength that ranges from about 300 nanometers to about 1.5 micrometers, and plate 904 is configured to change such light from the first polarization state to the second polarization state. An aperture 910 (whose location shown in FIG. 9 is approximate and not intended to be limiting) formed by stress pattern 900 is also shown. Aperture can be more than 10 mm, for example. The area of aperture 910 corresponds to an area where birefringence is slowly varying (e.g., as indicated by stress pattern 900 toward the center of plate 904).

Orientation 902 is a slow axis orientation. As described above, once force is applied to plate 904 by the actuators, plate 904 forms a waveplate. The waveplate is configured to shift a phase between two perpendicular polarization components of a light wave passing through plate 904 such that there is a phase difference between the different components after they pass through plate 904. For light entering plate 904, the component traveling along an optical axis of plate 904 travels at one speed, while the component traveling along a perpendicular axis travels with a different speed. The slow axis of plate 904 is perpendicular to the optical axis of plate 904. Orientation 902 shows the orientation of individual portions 912 of the slow axis around plate 904 that result from the birefringence. It should be noted that the birefringence of plate 904 changes from point to point across the cross-section, as does the slow/fast axis orientation. The region of interest that acts as a uniform waveplate is the center region (as shown and described herein).

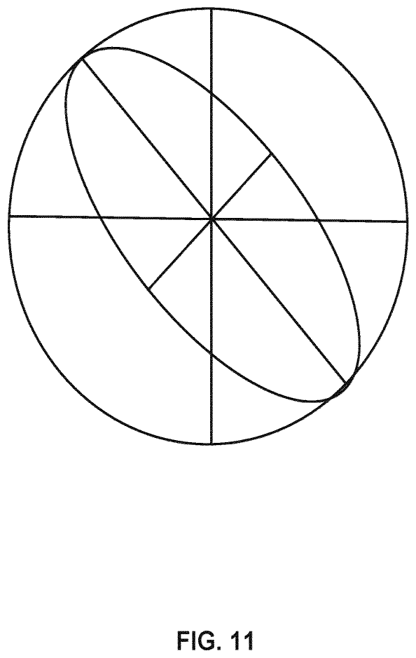

FIG. 10 illustrates an image 1001 of a plate 1003 (e.g., similar to and/or the same as plate 702 or 904 shown in FIG. 7 and FIG. 9 respectively) between two cross polarizers while forces are applied to plate 1003 by actuators (e.g., actuators 704 described above). The variation in color in image 1001 in FIG. 10 corresponds to varying stresses in plate 1003 caused by forces from actuators. In this example, the actuators are again not visible. However, locations 1005 that correspond to locations of the actuators are apparent. Note that an aperture is formed as indicated by the dark, non-varying color at the center of the image. Also note that the patterns shown in FIG. 10 (and FIG. 9) are dynamically adjustable as described herein, such that the patterns can be changed at sub-millisecond time intervals.

FIG. 11 illustrates a polarization state of light after it has passed through a center portion (e.g., an aperture) of a stress engineered optical plate (e.g., such as plates 702, 904, 1003, etc. shown in other figures), according to an embodiment. In this example, the light has a specific orientation, wavelength, power, ellipticity, and/or other characteristics imparted by the plate. As described above, in some embodiments, dynamic adjustments of forces applied to the plate comprise applications of different combinations of force magnitudes at different actuators around the plate to change birefringence in the plate with sub-millisecond control speeds. In some embodiments, dynamic adjustments comprise applications of different combinations of force magnitudes at different actuators around the plate to change an orientation in the plate with sub-millisecond control speeds. This control can be configured such that light that passes through the plate has specific properties as illustrated in FIG. 11. Note that FIG. 11 shows an elliptical state of polarization. But it can instead be a fully circular or fully linear state, which are special states of the elliptical state.

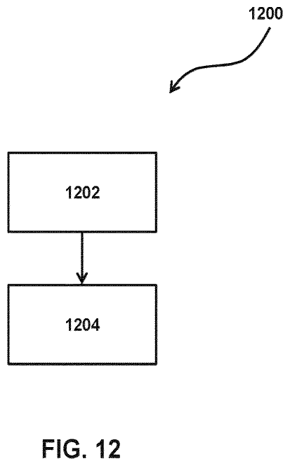

FIG. 12 illustrates a method 1200 for conditioning light for metrology. In some embodiments, conditioning the light for metrology is performed as part of a semiconductor device manufacturing process. In some embodiments, one or more operations of method 1200 may be implemented in or by system 700 illustrated in FIG. 7, and/or system 10 illustrated in FIGS. 3 and 4, a computer system (e.g., as illustrated in FIGS. 7 and 13 and described below), and/or in or by other systems, for example. In some embodiments, method 1200 comprises applying (operation 1202) forces to an optically transparent plate, controlling (operation 1204) the application of the forces to generate the stress pattern to impart a specific polarization to light passing through the plate in accordance with a desired metrology function. Method 1200 is described in the context of overlay measurement, but this is not intended to be limiting. Method 1200 may be generally applied to a number of different processes.

The operations of method 1200 presented below are intended to be illustrative. In some embodiments, method 1200 may be accomplished with one or more additional operations not described, and/or without one or more of the operations discussed. For example, in some embodiments, method 1200 may include an additional operation comprising determining an adjustment for a semiconductor device manufacturing process. Additionally, the order in which the operations of method 1200 are illustrated in FIG. 12 and described below is not intended to be limiting.

In some embodiments, one or more portions of method 1200 may be implemented in and/or controlled by one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 1200 in response to instructions stored electronically on an electronic storage medium. The one or more processing devices may include one or more devices configured through hardware, firmware, and/or software to be specifically designed for execution of one or more of the operations of method 1200 (e.g., see discussion related to FIG. 13 below).

At operation 1202, forces are applied to the optically transparent plate with one or more actuators to generate a stress pattern in the plate. The stress pattern comprises birefringence. The plate comprises a transparent material. For example, the plate may comprise glass or crystal. Responsive to the forces being applied to the plate to generate the stress pattern, the plate is configured to change the light passing through the plate from a first polarization state to a second polarization state. In some embodiments, the plate, along with the one or more actuators, and the one or more processors are configured such that the light passing through the plate can have a wavelength that ranges from about 300 nanometers to about 1.5 micrometers. The plate may be similar to and/or the same as plate 702 described above.

The one or more actuators are arranged on one or more edges of the plate. In some embodiments, the one or more actuators comprise a plurality of actuators distributed symmetrically around one or more edges of the plate. In some embodiments, the one or more actuators are piezoelectric. The actuators may be the same as and/or similar to actuators 704 also described above, for example.

In some embodiments, responsive to the forces being applied to the plate, the plate comprises a waveplate, for example. The forces applied by the actuators induce an orientation and a retardance in the plate. The orientation is controlled by locations and/or a distribution of forces applied to the plate by the one or more actuators. The retardance is controlled by magnitudes of forces applied to the plate by the one or more actuators. The induced retardance and orientation are not uniform. Each varies across the plate. A center region of the plate is an area of interest where the retardance and fast axis orientation is approximately uniform.

At operation 1204, one or more processors similar to and/or the same as processors PRO described above may be used to control the one or more actuators to apply the forces. The forces are configured to generate the stress pattern to impart a specific polarization to light passing through the plate in accordance with a desired metrology function. Imparting a specific polarization to the light comprises conditioning the light passing through the plate for metrology. The desired metrology function may be overlay measurement, for example. The one or more processors are configured to individually control each of the one or more actuators such that the stress pattern inside the plate is dynamically adjustable before, during, and/or after the light passes through the plate. In some embodiments, dynamic adjustments comprise applications of different combinations of force magnitudes at different actuators around the plate to change birefringence in the plate with sub-millisecond control speeds. In some embodiments, dynamic adjustments comprise applications of different combinations of force magnitudes at different actuators around the plate to change an orientation in the plate with sub-millisecond control speeds.

In some embodiments, method 1200 also includes irradiating a target (e.g., target 30 shown in FIG. 3 and FIG. 4) in a patterned substrate with radiation. The radiation comprises light and/or other radiation. The target may comprise one or more structures in the patterned substrate capable of providing a diffraction signal. The target may be included in a layer of a substrate in a semiconductor device structure, for example. In some embodiments, the feature comprises a geometric feature such as a 1D or 2D feature, and/or other geometric features. By way of several non-limiting examples, the feature may comprise a grating, a line, an edge, a fine-pitched series of lines and/or edges, and/or other features.

The radiation may have a target wavelength and/or wavelength range, a target intensity, and/or other characteristics. The target wavelength and/or wavelength range, the target intensity, etc., may be entered and/or selected by a user, determined by the system (e.g., system 10 shown in FIGS. 3 and 4, and/or system 700 shown in FIG. 7) based on previous overlay measurements, and/or determined in other ways. In some embodiments, the radiation comprises light and/or other radiation. In some embodiments, the light comprises visible light, infrared light, near infrared light, and/or other light. In some embodiments, the radiation may be any radiation appropriate for interferometry.

The radiation may be generated by a radiation source (e.g., projector 2 shown in FIGS. 3 and 4 and described above). In some embodiments, the radiation may be directed by the radiation source onto a target, sub-portions (e.g., something less than the whole) of a target, multiple targets, and/or onto the substrate in other ways. In some embodiments, the radiation may be directed by the radiation source onto the target in a time varying manner. For example, the radiation may be rastered over a target (e.g., by moving the target under the radiation) such that different portions of the target are irradiated at different times. As another example, characteristics of the radiation (e.g., wavelength, intensity, etc.) may be varied. This may create time varying data envelopes, or windows, for analysis. The data envelopes may facilitate analysis of individual sub-portions of a target, comparison of one portion of a target to another and/or to other targets (e.g., in other layers), and/or other analysis.

In some embodiments, method 1200 comprises detecting reflected radiation from the target. Detecting reflected radiation comprises detecting one or more phase and/or amplitude (intensity) shifts in reflected radiation from one or more geometric features of the target. The one or more phase and/or amplitude shifts correspond to one or more dimensions of a target. For example, the phase and/or amplitude of reflected radiation from one side of a target is different relative to the phase and/or amplitude of reflected radiation from another side of the target.

Detecting the one or more phase and/or amplitude (intensity) shifts in the reflected radiation from the target comprises measuring local phase shifts (e.g., local phase deltas) and/or amplitude variations that correspond to different portions of a target. For example, the reflected radiation from a specific area of a target may comprise a sinusoidal waveform having a certain phase and/or amplitude. The reflected radiation from a different area of the target (or a target in a different layer) may also comprise a sinusoidal waveform, but one with a different phase and/or amplitude. Detected reflected radiation also comprises measuring a phase and/or amplitude difference in reflected radiation of different diffraction orders. Detecting the one or more local phase and/or amplitude shifts may be performed using Hilbert transformations, for example, and/or other techniques. Interferometry techniques and/or other operations may be used to measure phase and/or amplitude differences in reflected radiation of different diffraction orders.

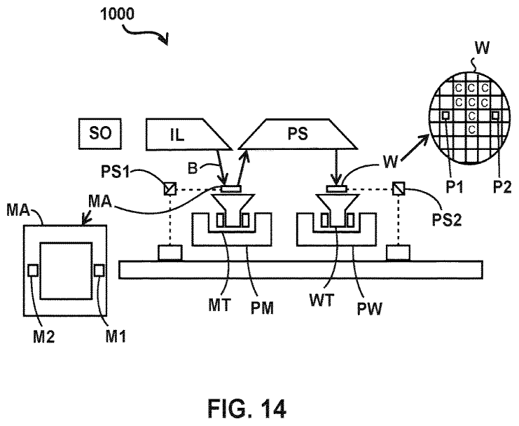

In some embodiments, method 1200 comprises generating a metrology signal based on the detected reflected radiation from the target. The metrology signal is generated by a sensor (such as detector 18 in FIG. 14, the camera in FIG. 8, and/or other sensors) based on light received by the sensor after the light passes through a polarizer (e.g., see FIG. 4 and FIG. 8) and the plate. The metrology signal comprises measurement information pertaining to the target. For example, the metrology signal may be an overlay signal comprising overlay measurement information, and/or other metrology signals. The measurement information (e.g., an overlay value and/or other information) may be determined using principles of interferometry and/or other principles.

The metrology signal comprises an electronic signal that represents and/or otherwise corresponds to the radiation reflected from the target(s). The metrology signal may indicate an overlay value associated with the target, for example, and/or other information. Generating the metrology signal comprises sensing the reflected radiation and converting the sensed reflected radiation into the electronic signal. In some embodiments, generating the metrology signal comprises sensing different portions of the reflected radiation from different areas and/or different geometries of the target, and/or multiple targets, and combining the different portions of the reflected radiation to form the metrology signal. This sensing and converting may be performed by components similar to and/or the same as detector 4, detector 18, and/or processors PRO shown in FIG. 3, FIG. 4, and FIG. 7, the camera shown in FIG. 8, and/or other components.

In some embodiments, generating the metrology signal may comprising directly measuring the dimensions and/or location of a target. For example, direct dimensional and/or location measurements of a target may be made with a scatterometer and/or other systems. In some embodiments, direct dimensional and/or location measurements may be used in combination with, and/or instead of the local phase and/or amplitude shifts described herein, to determine overlay and/or other parameters. For example, output (e.g., relative) dimensional and/or location measurements from the scatterometer system for different targets may be provided to processor PRO (FIG. 3, 4, 7) and/or other system components, which may generate the metrology signal based at least in part on the output dimensional measurements from the scatterometer system.

In some embodiments, method 1200 comprises determining an adjustment for a semiconductor device manufacturing process. In some embodiments, method 1200 includes determining one or more semiconductor device manufacturing process parameters. The one or more semiconductor device manufacturing process parameters may be determined based on one or more detected phase and/or amplitude variations, an overlay value indicated by the metrology signal, dimensions determined by a scatterometer system, and/or other similar systems, and/or other information. The one or more parameters may include a parameter of the radiation (the radiation used for determining overlay), an overlay value, an alignment inspection location on a layer of a semiconductor device structure, a radiation beam trajectory across a target, and/or other parameters. In some embodiments, process parameters can be interpreted broadly to include a stage position, a mask design, a metrology target design, a semiconductor device design, an intensity of the radiation (used for exposing resist, etc.), an incident angle of the radiation (used for exposing resist, etc.), a wavelength of the radiation (used for exposing resist, etc.), a pupil size and/or shape, a resist material, and/or other parameters.

In some embodiments, method 1200 includes determining a process adjustment based on the one or more determined semiconductor device manufacturing process parameters, adjusting a semiconductor device manufacturing apparatus based on the determined adjustment, and/or other operations. For example, if a determined overlay is not within process tolerances, the out of tolerance overlay may be caused by one or more manufacturing processes whose process parameters have drifted and/or otherwise changed so that the process is no longer producing acceptable devices (e.g., overlay measurements may breach a threshold for acceptability). One or more new or adjusted process parameters may be determined based on the overlay determination. The new or adjusted process parameters may be configured to cause a manufacturing process to again produce acceptable devices. For example, a new or adjusted process parameter may cause a previously unacceptable overlay value to be adjusted back into an acceptable range. The new or adjusted process parameters may be compared to existing parameters for a given process. If there is a difference, that difference may be used to determine an adjustment for an apparatus that is used to produce the devices (e.g., parameter “x” should be increased/decreased/changed so that it matches the new or adjusted version of parameter “x” determined as part of method 1200), for example. In some embodiments, method 1200 may include electronically adjusting an apparatus (e.g., based on the determined process parameters). Electronically adjusting an apparatus may include sending an electronic signal, and/or other communications to the apparatus, for example, that causes a change in the apparatus. The electronic adjustment may include changing a setting on the apparatus, for example, and/or other adjustments.

FIG. 13 is a diagram of an example computer system CS that may be used for one or more of the operations described herein. Computer system CS may be the same as or similar to the computer system shown in FIG. 7 and described above. Computer system CS includes a bus BS or other communication mechanism for communicating information, and a processor PRO (or multiple processors) similar to and/or the same as the processor(s) shown in FIG. 7 and described above, coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more operations described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” or “machine-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

FIG. 14 schematically depicts an exemplary lithographic projection apparatus similar to and/or the same as the apparatus shown in FIG. 1 that can be used in conjunction with the techniques described herein. The apparatus 1000 comprises an illumination system IL, to condition a beam B of radiation. In this particular case, the illumination system also comprises a radiation source SO; a first object table (e.g., patterning device table) MT provided with a patterning device holder to hold a patterning device MA (e.g., a reticle), and connected to a first positioner PM (working in association with a first position sensor) PSI to accurately position the patterning device; a second object table (substrate table) WT provided with a substrate holder to hold a substrate W (e.g., a resist-coated silicon wafer), and connected to a second positioner PW (working in association with a second position sensor PS2) to accurately position the substrate; a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means for setting the outer and/or inner radial extent (commonly referred to as σ-outer and σ-inner, respectively) of the intensity distribution in the beam. In addition, it will generally comprise various other components, such as an integrator and a condenser. In this way, the beam B impinging on the patterning device MA has a desired uniformity and intensity distribution in its cross-section.

It should be noted with regard to FIG. 14 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

The beam B subsequently intercepts the patterning device MA, which is held on a patterning device table MT. Having traversed the patterning device MA, the beam B passes through a lens, which focuses the beam B onto a target portion C of the substrate W. With the aid of the second positioning means (and interferometric measuring means), the substrate table WT can be moved accurately, e.g. to position different target portions C in the path of the beam B. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted. However, in the case of a stepper (as opposed to a step-and-scan tool) the patterning device table MT may just be connected to a short stroke actuator, or may be fixed.

The depicted tool (similar to or the same as the tool shown in FIG. 1) can be used in two different modes. In step mode, the patterning device table MT is kept essentially stationary, and an entire patterning device image is projected in one operation (i.e., a single “flash”) onto a target portion C. The substrate table WT is then shifted in the x and/or y directions so that a different target portion C can be irradiated by the beam B. In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

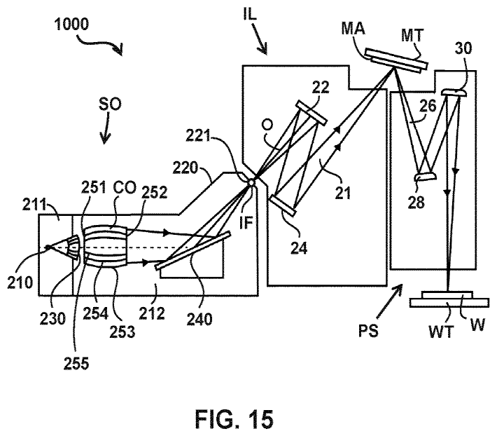

FIG. 15 shows the apparatus 1000 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the hot plasma 210 is created to emit radiation in the EUV range of the electromagnetic spectrum. The plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap 230 further indicated herein at least includes a channel structure.

The source chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation beam 21 at the patterning device MA, held by the support structure MT, a patterned beam 26 is formed and the patterned beam 26 is imaged by the projection system PS via reflective elements 28, 330 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 15.

Collector optic CO, as illustrated in FIG. 15, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

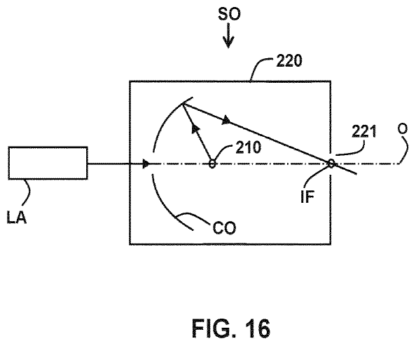

Alternatively, the source collector module SO may be part of an LPP radiation system as shown in FIG. 16. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

Various embodiments of the present systems and methods are disclosed in the subsequent list of numbered clauses:
1. A system configured to condition light for metrology, the system comprising: an optically transparent plate; one or more actuators configured to apply forces to the plate to generate a stress pattern in the plate; and one or more processors configured to control the one or more actuators to apply the forces to generate the stress pattern to impart a specific polarization to light passing through the plate in accordance with a desired metrology function.
2. The system of clause 1, wherein, responsive to the forces being applied to the plate, the plate comprises a waveplate.
3. The system of any of the previous clauses, wherein the plate comprises a transparent material, and wherein, responsive to the forces being applied to the plate to generate the stress pattern, the plate is configured to change the light passing through the plate from a first polarization state to a second polarization state.
4. The system of any of the previous clauses, wherein the applied forces induce an orientation and a retardance in the plate.
5. The system of any of the previous clauses, wherein the orientation is controlled by locations and/or a distribution of forces applied to the plate by the one or more actuators.
6. The system of any of the previous clauses, wherein the retardance is controlled by magnitudes of forces applied to the plate by the one or more actuators.
7. The system of any of the previous clauses, wherein the plate comprises glass or crystal.
8. The system of any of the previous clauses, wherein the one or more actuators are piezoelectric.
9. The system of any of the previous clauses, wherein the stress pattern comprises birefringence.
10. The system of any of the previous clauses, wherein the one or more processors are configured to individually control each of the one or more actuators such that the stress pattern inside the plate is dynamically adjustable before, during, and/or after the light passes through the plate.
11. The system of any of the previous clauses, wherein dynamic adjustments comprise applications of different combinations of force magnitudes at different actuators around the plate to change birefringence in the plate with sub-millisecond control speeds.
12. The system of any of the previous clauses, wherein dynamic adjustments comprise applications of different combinations of force magnitudes at different actuators around the plate to change an orientation in the plate with sub-millisecond control speeds.
13. The system of any of the previous clauses, wherein the one or more actuators are arranged on one or more edges of the plate.
14. The system of any of the previous clauses, wherein the one or more actuators comprise a plurality of actuators distributed symmetrically around one or more edges of the plate.
15. The system of any of the previous clauses, wherein the plate, the one or more actuators, and the one or more processors are configured such that the light passing through the plate can have a wavelength that ranges from about 300 nanometers to about 1.5 micrometers.
16. The system of any of the previous clauses, wherein imparting a specific polarization to the light comprises conditioning the light passing through the plate for metrology.
17. The system of any of the previous clauses, wherein the system further comprises a polarizer and a sensor, wherein the sensor is configured to generate a metrology signal based on light received by the sensor after the light passes through the polarizer and the plate.
18. The system of any of the previous clauses, wherein the sensor is included in a camera.
19. The system of any of the previous clauses, further comprising an imaging lens positioned between the plate and the sensor.
20. The system of any of the previous clauses, wherein the metrology signal comprises an overlay signal associated with a semiconductor manufacturing process.
21. A method for conditioning light for metrology, the method comprising: applying forces to an optically transparent plate with one or more actuators to generate a stress pattern in the plate; and controlling, with one or more processors, the one or more actuators to apply the forces to generate the stress pattern to impart a specific polarization to light passing through the plate in accordance with a desired metrology function.
22. The method of clause 21, wherein, responsive to the forces being applied to the plate, the plate comprises a waveplate.
23. The method of any of the previous clauses, wherein the plate comprises a transparent material, and wherein, responsive to the forces being applied to the plate to generate the stress pattern, the plate is configured to change the light passing through the plate from a first polarization state to a second polarization state.
24. The method of any of the previous clauses, wherein the applied forces induce an orientation and a retardance in the plate.
25. The method of any of the previous clauses, wherein the orientation is controlled by locations and/or a distribution of forces applied to the plate by the one or more actuators.
26. The method of any of the previous clauses, wherein the retardance is controlled by magnitudes of forces applied to the plate by the one or more actuators.
27. The method of any of the previous clauses, wherein the plate comprises glass or crystal.
28. The method of any of the previous clauses, wherein the one or more actuators are piezoelectric.
29. The method of any of the previous clauses, wherein the stress pattern comprises birefringence.
30. The method of any of the previous clauses, wherein the one or more processors are configured to individually control each of the one or more actuators such that the stress pattern inside the plate is dynamically adjustable before, during, and/or after the light passes through the plate.
31. The method of any of the previous clauses, wherein dynamic adjustments comprise applications of different combinations of force magnitudes at different actuators around the plate to change birefringence in the plate with sub-millisecond control speeds.
32. The method of any of the previous clauses, wherein dynamic adjustments comprise applications of different combinations of force magnitudes at different actuators around the plate to change an orientation in the plate with sub-millisecond control speeds.
33. The method of any of the previous clauses, wherein the one or more actuators are arranged on one or more edges of the plate.
34. The method of any of the previous clauses, wherein the one or more actuators comprise a plurality of actuators distributed symmetrically around one or more edges of the plate.
35. The method of any of the previous clauses, wherein the plate, the one or more actuators, and the one or more processors are configured such that the light passing through the plate can have a wavelength that ranges from about 300 nanometers to about 1.5 micrometers.
36. The method of any of the previous clauses, wherein imparting a specific polarization to the light comprises conditioning the light passing through the plate for metrology.
37. The method of any of the previous clauses, wherein the method further comprises generating, with a sensor, a metrology signal based on light received by the sensor after the light passes through a polarizer and the plate.
38. The method of any of the previous clauses, wherein the sensor is included in a camera.
39. The method of any of the previous clauses, further comprising passing the light through an imaging lens positioned between the plate and the sensor.
40. The method of any of the previous clauses, wherein the metrology signal comprises an overlay signal associated with a semiconductor manufacturing process.
41. A non-transitory computer readable medium having instructions thereon, the instructions when executed by a computer, causing operations comprising: applying forces to an optically transparent plate with one or more actuators to generate a stress pattern in the plate; and controlling, with one or more processors, the one or more actuators to apply the forces to generate the stress pattern to impart a specific polarization to light passing through the plate in accordance with a desired metrology function.
42. The medium of clause 41, wherein, responsive to the forces being applied to the plate, the plate comprises a waveplate.
43. The medium of any of the previous clauses, wherein the plate comprises a transparent material, and wherein, responsive to the forces being applied to the plate to generate the stress pattern, the plate is configured to change the light passing through the plate from a first polarization state to a second polarization state.
44. The medium of any of any of the previous clauses, wherein the applied forces induce an orientation and a retardance in the plate.
45. The medium of any of the previous clauses, wherein the orientation is controlled by locations and/or a distribution of forces applied to the plate by the one or more actuators.
46. The medium of any of the previous clauses, wherein the retardance is controlled by magnitudes of forces applied to the plate by the one or more actuators.
47. The medium of any of the previous clauses, wherein the plate comprises glass or crystal.
48. The medium of any of the previous clauses, wherein the one or more actuators are piezoelectric.
49. The medium of any of the previous clauses, wherein the stress pattern comprises birefringence.
50. The medium of any of the previous clauses, wherein the one or more processors are configured by the instructions to individually control each of the one or more actuators such that the stress pattern inside the plate is dynamically adjustable before, during, and/or after the light passes through the plate.
51. The medium of any of the previous clauses, wherein dynamic adjustments comprise applications of different combinations of force magnitudes at different actuators around the plate to change birefringence in the plate with sub-millisecond control speeds.
52. The medium of any of the previous clauses, wherein dynamic adjustments comprise applications of different combinations of force magnitudes at different actuators around the plate to change an orientation in the plate with sub-millisecond control speeds.
53. The medium of any of the previous clauses, wherein the one or more actuators are arranged on one or more edges of the plate.
54. The medium of any of the previous clauses, wherein the one or more actuators comprise a plurality of actuators distributed symmetrically around one or more edges of the plate.
55. The medium of any of the previous clauses, wherein the plate, the one or more actuators, and the one or more processors are configured such that the light passing through the plate can have a wavelength that ranges from about 300 nanometers to about 1.5 micrometers.
56. The medium of any of the previous clauses, wherein imparting a specific polarization to the light comprises conditioning the light passing through the plate for metrology.
57. The medium of any of the previous clauses, wherein the instructions further cause operations comprising generating, with a sensor, a metrology signal based on light received by the sensor after the light passes through a polarizer and the plate.
58. The medium of any of the previous clauses, wherein the sensor is included in a camera.
59. The medium of any of the previous clauses, wherein the light also passes through an imaging lens positioned between the plate and the sensor.
60. The medium of any of the previous clauses, wherein the metrology signal comprises an overlay signal associated with a semiconductor manufacturing process.
61. A system configured to condition light for an overlay measurement as part of a semiconductor manufacturing process, the system configured to dynamically adjust birefringence and/or an orientation in an optical plate before, during, and/or after light passes through the plate, the dynamic adjustments comprising applications of different combinations of force magnitudes at different actuators around the plate to change the birefringence and/or the orientation in the plate with sub-millisecond control speeds, the system comprising: the plate, wherein the plate comprises a transparent material and is configured to change the light passing through the plate from a first polarization state to a second polarization state responsive to forces being applied to the plate by the different actuators; the different actuators, the different actuators comprising a plurality of piezoelectric actuators distributed symmetrically around one or more edges of the plate, the plurality of piezoelectric actuators configured to apply forces to the plate to generate the birefringence and/or the orientation; and one or more processors configured to individually control each one of the plurality of actuators to apply the forces to generate the birefringence and/or the orientation such that a specific polarization is imparted to the light passing through the plate that changes the light to the second polarization state.
62. The system of any of the previous clauses, wherein responsive to the forces being applied to the plate, the plate is characterized by the orientation and a retardance.
63. The system of any of the previous clauses, wherein the orientation is controlled by locations and/or a distribution of forces applied to the waveplate by the plurality of actuators; and wherein the retardance is controlled by magnitudes of forces applied to the waveplate by the plurality of actuators.
64. The system of any of the previous clauses, wherein the plate, the plurality of actuators, and the one or more processors are configured such that the light passing through the plate can have a wavelength that ranges from about 300 nanometers to about 1.5 micrometers.
65. The system of any of the previous clauses, wherein the system further comprises a polarizer and a sensor, wherein the sensor is configured to generate a metrology signal based on light received by the sensor after the light passes through the polarizer and the plate; and wherein the metrology signal comprises an overlay signal associated with a semiconductor manufacturing process.

The concepts disclosed herein may be associated with any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers. In addition, the combination and sub-combinations of disclosed elements may comprise separate embodiments.

The descriptions above are intended to be illustrative, not limiting. Thus, it will be apparent to one skilled in the art that modifications may be made as described without departing from the scope of the claims set out below.

1. A system configured to condition light for metrology, the system comprising:
an optically transparent plate;
one or more actuators configured to apply force to the plate to generate a stress pattern in the plate; and
one or more processors configured to control the one or more actuators to apply the force to generate the stress pattern to impart a specific polarization to light passing through the plate in accordance with a desired metrology function.

2. The system of claim 1, wherein, responsive to the force being applied to the plate, the plate comprises a waveplate.

3. The system of claim 1, wherein the plate comprises a transparent material, and wherein, responsive to the force being applied to the plate to generate the stress pattern, the plate is configured to change the light passing through the plate from a first polarization state to a second polarization state.

4. The system of claim 1, wherein the applied force induces an orientation and a retardance in the plate.

5. The system of claim 4, wherein the orientation is controlled by a location and/or distribution of force applied to the plate by the one or more actuators.

6. The system of claim 4, wherein the retardance is controlled by a magnitude of force applied to the plate by the one or more actuators.

7. The system of claim 1, wherein the plate comprises glass or crystal.

8. The system of claim 1, wherein the one or more actuators are piezoelectric.

9. The system of claim 1, wherein the stress pattern comprises birefringence.

10. The system of claim 1, wherein the one or more processors are configured to individually control each of the one or more actuators such that the stress pattern inside the plate is dynamically adjustable before, during, and/or after the light passes through the plate.

11. The system of claim 10, wherein dynamic adjustment comprises applications of different combinations of force magnitudes at different actuators around the plate to change birefringence in the plate with sub-millisecond control speeds.

12. The system of claim 10, wherein dynamic adjustment comprises applications of different combinations of force magnitudes at different actuators around the plate to change an orientation in the plate with sub-millisecond control speeds.

13. The system of claim 1, wherein the one or more actuators are arranged on one or more edges of the plate.

14. The system of claim 1, wherein the one or more actuators comprise a plurality of actuators distributed symmetrically around one or more edges of the plate.

15. The system of any of claim 1, wherein the plate, the one or more actuators, and the one or more processors are configured such that the light passing through the plate can have a wavelength that ranges from about 300 nanometers to about 1.5 micrometers.

16. The system of claim 1, wherein imparting of a specific polarization to the light comprises conditioning of the light passing through the plate for metrology.

17. The system of claim 1, further comprising a polarizer and a sensor, wherein the sensor is configured to generate a metrology signal based on light received by the sensor after the light passes through the polarizer and the plate.

18. The system of claim 17, wherein the sensor is included in a camera.

19. The system of claim 17, further comprising an imaging lens positioned between the plate and the sensor.

20. The system of claim 17, wherein the metrology signal comprises an overlay signal associated with a semiconductor manufacturing process.
